(19) United States
(12) Patent Application Publication
(10) Pub. No.: US 2024/0109152 A1
(43) Pub. Date: Apr. 4, 2024

(54) COMBINED DUAL-WAVELENGTH LASER LIGHT PROCESSING DEVICE

(71) Applicant: SYU GUANG TECHNOLOGY CO., LTD., Zhubei City (TW)

(72) Inventors: Kun Yu Wu, Zhubei City (TW); Ming Tsung Tsai, Taoyuan City (TW)

(21) Appl. No.: 18/302,971

(22) Filed: Apr. 19, 2023

(30) Foreign Application Priority Data
Sep. 30, 2022 (TW) 111137306

(51) Int. Cl. B23K 26/082; B23K 26/06; G02B 26/08; G02B 26/10; G02B 27/09; G02B 27/14

(52) U.S. Cl. CPC B23K 26/082; B23K 26/0604; B23K 26/0643; B23K 26/0648; G02B 26/0816; G02B 26/101; G02B 27/0916; G02B 27/0927; G02B 27/0955; G02B 27/14; H01L 21/67092

(57) ABSTRACT

The invention relates to a combined dual-wavelength laser light processing device, having two laser light source and a Bessel beam lens, so as to form a Bessel beam with long focal length; Using the coaxial reflecting mirror to achieve deflecting and penetrating to form two coaxial finished light beams; a diffraction optical unit for adjusting the energy distribution of the finished light beam; a work platform; a laser galvanometric scanning module to achieve guiding the finished light beam; a controller electrically connected to the two laser light sources, and controls the projection timing and energy of the first and the second wavelength beams to form at least one rectangular pulse and at least one burst pulse, through the repeated conversion of the dual wavelengths in the composite light wave configuration make the processing of the composite material to be fast and precise.

### BACKGROUND OF THE INVENTION

### 1. Field of the Invention

The invention relates to a combined dual-wavelength laser light processing device, especially to one that control two kinds of wavelength beams to form a composite light wave configuration with the same optical axis, and then through repeated conversion of double wavelengths, the processing of composite materials can achieve fast and accurate results.

### 2. Description of the Related Art

In recent years, laser cutting technology has been widely used to cut hard and transparent materials such as light-emitting diode substrates or tempered glass; laser cutting technology is using laser light focus on the processed material to produce local thermal melting damage, wherein the laser light source mainly includes a high-energy laser beam and uses an energy controller to regulate the energy of the laser beam.

Laser applications in various processes have become more and more popular, and most of them use lasers with 1064 nm wavelength and 532 nm wavelength to meet different requirements; for example, in the electronics industry, 1064 nm wavelength is used to calibrate embedded carbon film resistors, and 532 nm wavelength is used to calibrate the resistance of metal alloys; in the semiconductor back-end process, 1064 nm wavelength is used for film printing, and 532 nm wavelength is used to cut wafers; in the consumer electronics industry, 1064 nm and 532 nm wavelength lasers are used to cut flash memory to form special shapes.

Semiconductor wafer 100, as shown in FIG. 1, having a plurality of chips 100a or grains 100b formed on its upper surface; to separate the chips 100a and grains 100b from the semiconductor wafer 100, the semiconductor wafer 100 are covered with a series of vertical scribe line or saw lane 102, 104. The process of separating the wafers is known as “wafer dicing”. The wafers are covered with many different layers, such as protective layers of oxide or nitride, dielectric layers, polymer films, and metal pads of aluminum and copper; wherein, the different materials have non-homogeneity, so that will cause great trouble when the wafer is diced during the manufacturing process. The current method in the industry is to use a double-cutting method with two wavelengths of lasers; firstly, the protective layer is cut by the laser beam of the first wavelength, and after the cutting of the protective layer is completed, using the laser beam of the second wavelength to cut the material of the lower layer of the substrate; however, in the separate two-pass construction method, the work piece must be displaced twice, which wastes working hours and energy. Moreover, the interval between the two passes is very long, and the material of the protective layer is easily fused again and affects the cutting operation of the second pass; therefore, how to shorten the working hours and reduce energy waste while ensuring the quality of the wafer dicing process has become a subject of the present invention.

### SUMMARY OF THE INVENTION

It is a primary objective of the present invention to provide a combined dual-wavelength laser light processing device designed for wafer dicing.

It is another objective of the present invention to provide a coaxial composite light wave configuration that can control two kinds of wavelength beam, and then through the repeated conversion of the dual wavelengths in the composite light wave configuration make the processing of the composite material to be fast and precise.

It is another objective of the present invention to provide a laser light processing device that guides the finished light beam through the galvanometer scanning module so as to process the work piece without shifting the work platform.

In order to achieve the above objectives, the present invention including: a first laser light source for emitting a first wavelength beam; a second laser light source for emitting a second wavelength beam, arranged at the lateral side of the first laser light source; at least one Bessel beam lens is arranged behind one of the first laser light source or second laser light source, so that one of the first wavelength beam or second wavelength beam forms a Bessel beam; a coaxial reflecting mirror composed of two triangular prism mirrors, the combination surfaces of the triangular prism mirrors are individually coated with a coating, the coaxial reflecting mirror is correspondingly arranged on the optical path of the Bessel beam and the wavelength beam of the first wavelength beam or second wavelength beam, so as to form a coaxial finished light beam, and the finished light beam includes a first finished light beam and a finished light beam; a diffraction optical unit is arranged behind the coaxial reflecting mirror and on the optical path of the finished light beam, for adjusting the energy distribution of the finished light beam; a work platform for supporting a work piece for processing operations; a laser galvanometric scanning module is arranged behind the diffraction optical unit and above the work platform, so as to achieve guiding the finished light beam to the work platform; a controller electrically connected to the first laser light source, the second laser light source and the laser galvanometric scanning module, wherein the controller timely adjusts the angle of the laser galvanometric scanning module during processing, so as to achieve guiding the finished light beam projected to any position of the two-dimensional coordinates of the work platform; the controller controls the projection timing and energy of the first wavelength beam and the second wavelength beam, and make the first finished light beam and the second finished light beam combine to form a composite light wave configuration with at least one rectangular pulse and at least one burst pulse, and then through the repeated conversion of the dual wavelengths in the composite light wave configuration make the processing of the composite material to be fast and precise.

The present invention has another method including: a first laser light source for emitting a first wavelength beam; a second laser light source for emitting a second wavelength beam, arranged at the lateral side of the first laser light source; a coaxial reflecting mirror and a second reflecting mirror are arranged on the optical path of the first wavelength beam and the second wavelength beam correspondingly, the second reflecting mirror deflects the second wavelength beam to the coaxial reflecting mirror, and the coaxial reflecting mirror are composed of two triangular prism mirrors, the combination surfaces of the triangular prism mirrors are individually coated with a coating, which allow the incoming first wavelength beam to penetrate and the second wavelength beam to deflect, so as to form a coaxial finished light beam, and the finished light beam includes a first finished light beam and a finished light beam; a diffraction optical unit is arranged behind the coaxial reflecting mirror and on the optical path of the finished light beam, for adjusting the energy distribution of the finished light beam; a work platform for supporting a work piece for processing operations; a laser galvanometric scanning module is arranged behind the diffraction optical unit and above the work platform, so as to achieve guiding the finished light beam to the work platform; a multi focal length lens arranged between the laser galvanometric scanning module and the work platform for precisely focusing the finished light beam on the work piece; a controller electrically connected to the first laser light source, the second laser light source and the laser galvanometric scanning module, wherein the controller timely adjusts the angle of the laser galvanometric scanning module during processing, so as to achieve guiding the finished light beam projected to any position of the two-dimensional coordinates of the work platform; the controller controls the projection timing and energy of the first wavelength beam and the second wavelength beam, and make the first finished light beam and the second finished light beam combine to form a composite light wave configuration with at least one rectangular pulse and at least one burst pulse, and then through the repeated conversion of the dual wavelengths in the composite light wave configuration make the processing of the composite material to be fast and precise.

Also, the first wavelength beam has a wavelength of 532 nm, and the second wavelength beam has a wavelength of 1064 nm.

Also, the Bessel beam lens has an axicon lens, multiple lenses, and a spatial filter to form a Bessel beam with long focal length.

Also, the Bessel beam lens is a first Bessel beam lens, the Bessel beam is a first Bessel beam.

Also, the present invention further includes a second Bessel beam lens, which corresponds to the first Bessel beam lens, and is arranged behind one of the other first laser light source or second the laser light source, so as to make one of the other first wavelength beam or second wavelength beam to form a second Bessel beam; and the coaxial reflecting mirror is correspondingly arranged on the optical path of the first Bessel beam and the second Bessel beam to form a coaxial finished light beam.

Also, the coaxial reflecting mirror is correspondingly arranged on the optical path of the first Bessel beam, a second reflecting mirror is correspondingly arranged on the optical path of the second Bessel beam, the second reflecting mirror deflects the second Bessel beam to the coaxial reflecting mirror, and the coating of the coaxial reflecting mirror allows the incoming first Bessel beam to penetrate and the second Bessel beam to deflect, so as to form a coaxial finished light beam.

Also, the present invention further includes a first reflecting mirror and a second reflecting mirror correspondingly arranged on the optical path of the first Bessel beam and the second Bessel beam, deflect the first Bessel beam and the second Bessel beam to the coaxial reflecting mirror, and the coating of the coaxial reflecting mirror allows the incoming first Bessel beam and the second Bessel beam to deflect, so as to form a coaxial finished light beam.

Also, the laser galvanometric scanning module has a third reflecting mirror and a X-Y scan lens, and by the reflection of the third reflecting mirror and the focusing of the X-Y scan lens, the finished light beam is guided to project on the required processing point of the work piece.

Also, the controller includes a master oscillator power-amplifier or an acousto optic modulator for controlling the projection timing and energy of the first wavelength beam and the second wavelength beam, and make the first finished light beam and the second finished light beam combine to form a composite light wave configuration.

Also, the composite light wave configuration has a first composite light wave configuration with a periodic cycle, which includes a rectangular pulse A, a rectangular pulse B, and a burst pulse A in sequence, each pulses has a retention time their own, and the wavelength of the rectangular pulse A the rectangular pulse B, also the height and width of the burst pulse A can be adjusted.

Also, the composite light wave configuration has a second composite light wave configuration with a periodic cycle, which includes a rectangular pulse A, a burst pulse A, a rectangular pulse B, and a burst pulse B in sequence, each pulses has a retention time their own, and the wavelength of the rectangular pulse A the rectangular pulse B, also the height and width of the burst pulse A and the burst pulse B be adjusted.

With features disclosed above, the present invention arranges the Bessel beam lens after the laser light source, so as to form a Bessel beam with long focal length; Using the coating of the coaxial reflecting mirror, so as to make the Bessel beam to form a coaxial finished light beam; Making the controller electrically connected to the two laser light sources, and using the controller controls the projection timing and energy of the first wavelength beam and the second wavelength beam, and make the finished light beams to form a composite light wave configuration with at least one rectangular pulse and at least one burst pulse, wherein the first composite light wave configuration has two rectangular pulses and one burst pulse, the second composite light wave configuration has two rectangular pulses and two burst pulses, and the wavelength of the rectangular pulse≤the burst pulse; the present invention uses the repeated conversion of the dual wavelengths of the rectangular pulses A and the rectangular pulses B in the composite light wave configuration to cut the protective layer of the wafer with the rectangular pulses A of the wavelength of 532 nm, and then cuts the material of the lower layer of the substrate with the rectangular pulses B of the wavelength of 1064 nm, so as to solve the disadvantage of two individual displacements required in the conventional wafer dicing; Therefore the present invention can achieve rapid and precise results in the processing of composite materials. Moreover, the present invention can use the characteristics of the rectangular pulse which releasing huge energy instantaneously in the composite light wave configuration, and the characteristics of the burst pulse which avoiding energy failure through vibration, so the present invention can be applied to the processing of multi-layer structures of different materials, and it make the finished light beam to achieve low energy consumption, narrow working hot spots, and high aspect ratio processing benefits. Moreover, the present invention uses the controller to control the reflection of the third reflecting mirror in the laser galvanometric scanning module and the focusing of the X-Y scan lens, so as to achieve guiding the finished light beam to any position of the two-dimensional coordinates of the work platform; since there is no need to displace the work platform during laser processing of the work piece, therefore, the present invention can greatly improve the working efficiency.

### BRIEF DESCRIPTION OF THE DRAWINGS

FIG. 1 is a schematic diagram illustrating the structure of the semiconductor wafer dicing of the prior art;

FIG. 2A is a schematic diagram illustrating the structure of the first embodiment of the present invention;

FIG. 2B is a schematic diagram illustrating the structure of the second embodiment of the present invention;

FIG. 2C is a schematic diagram illustrating the structure of the third embodiment of the present invention;

FIG. 3A is a schematic diagram illustrating the structure of the Bessel beam lens of the present invention;

FIG. 3B is a schematic diagram illustrating the structure of the multi focal length lens of the present invention;

FIG. 4A is a schematic diagram illustrating the first kind of the structure of the coaxial reflecting mirror of the present invention;

FIG. 4B is a schematic diagram illustrating the second kind of the structure of the coaxial reflecting mirror of the present invention;

FIG. 5 is a schematic diagram illustrating the structure of the first composite light wave configuration of the present invention;

FIG. 6 is a schematic diagram illustrating the structure of the second composite light wave configuration of the present invention.

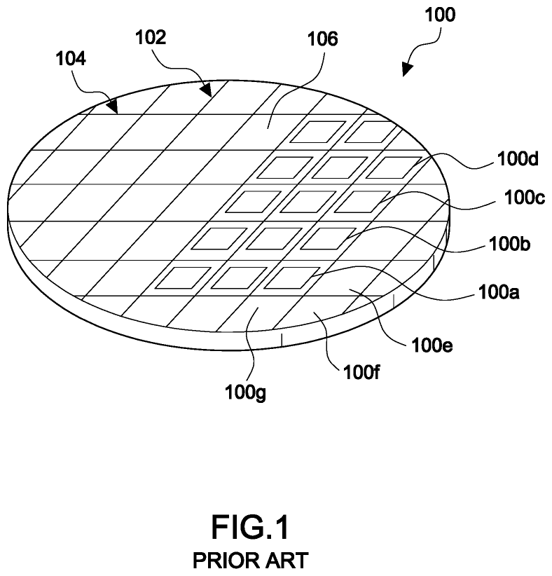

### DETAILED DESCRIPTION OF THE PREFERRED EMBODIMENT

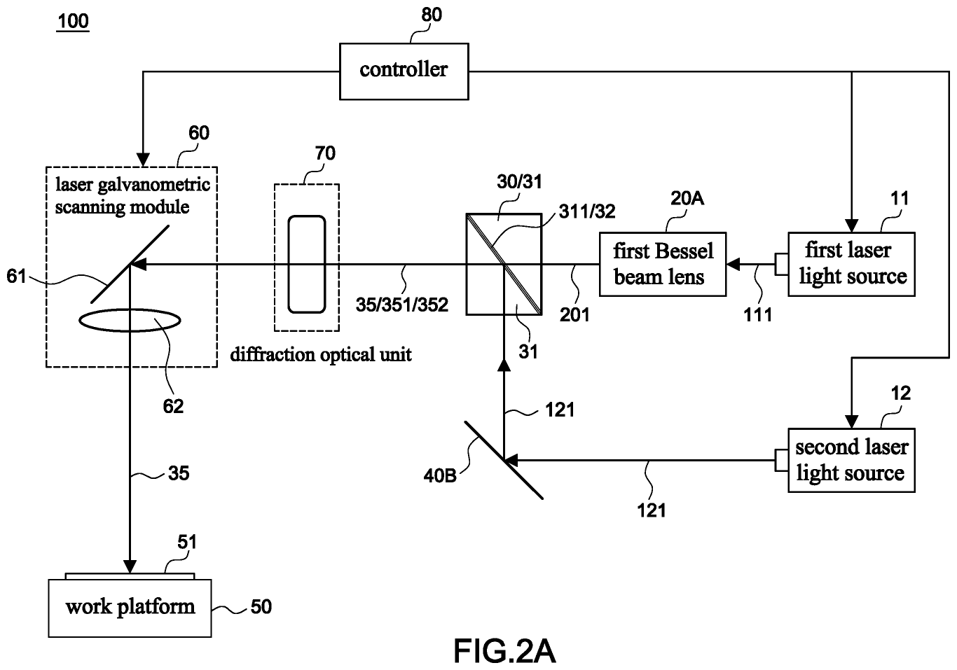

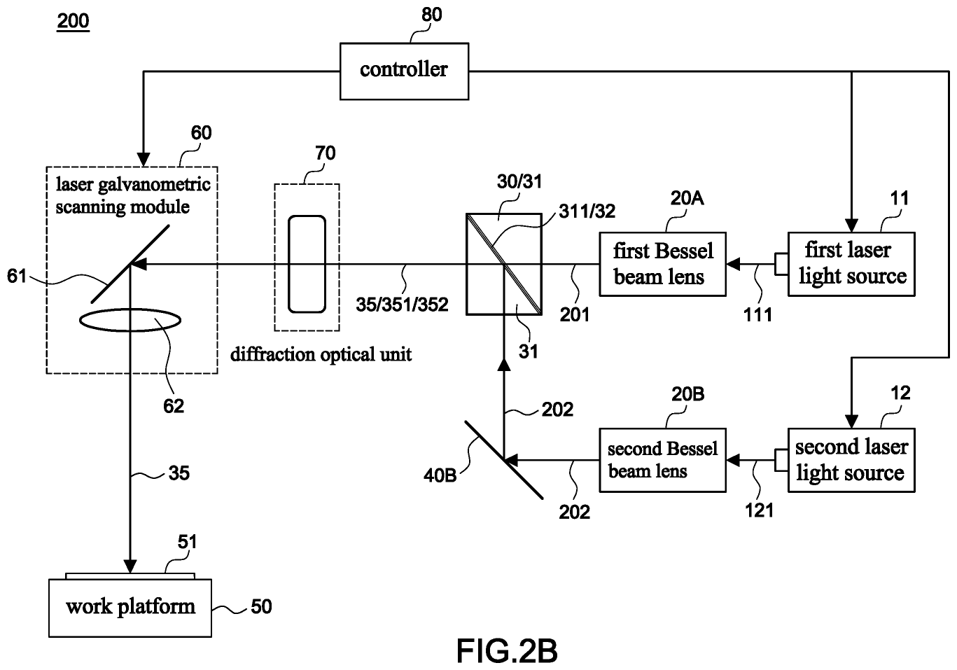

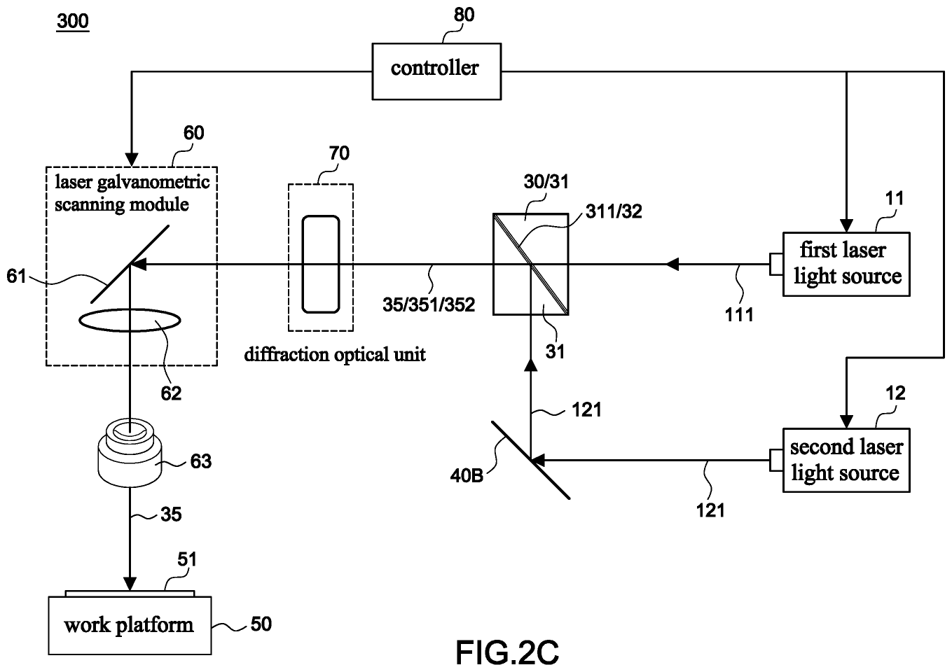

Referring to FIG. 2A, the first embodiment 100 of the present invention, including: a first laser light source 11 for emitting a first wavelength beam 111 with wavelength of 532 nm; a second laser light source 12 for emitting a second wavelength beam 121 with wavelength of 1064 nm, arranged at the lateral side of the first laser light source 11; a first Bessel beam lens 20A is arranged behind one of the first laser light source 11 to forms a first Bessel beam 201; a coaxial reflecting mirror 30 arranged on the optical path of the first Bessel beam 201, a second reflecting mirror 40B is arranged on the optical path of the second wavelength beam 121, the second reflecting mirror 40B deflects the second wavelength beam 121 to the coaxial reflecting mirror 30, and the coaxial reflecting mirror 30 is composed of two triangular prism mirrors 31, the combination surfaces 311 of the triangular prism mirrors 31 are individually coated with a coating 32 allowing the incoming first Bessel beam 201 and the second wavelength beam 121 to form a coaxial finished light beam 35, and the finished light beam 35 includes a first finished light beam 351 and a second finished light beam 352; a diffraction optical unit 70 is arranged behind the coaxial reflecting mirror 30 and on the optical path of the finished light beam 35, for adjusting the energy distribution of the finished light beam 35; a work platform 50 for supporting a work piece 51 for processing operations; a laser galvanometric scanning module 60 is arranged behind the diffraction optical unit 70 and above the work platform 50, the laser galvanometric scanning module 60 has a third reflecting mirror 61 and a X-Y scan lens 62, and by the reflection of the third reflecting mirror 61 and the focusing of the X-Y scan lens 62, the finished light beam 35 is guided to project on the required processing point of the work piece 51; a controller 80 includes a master oscillator power-amplifier or an acousto optic modulator, the master oscillator power-amplifier can achieve high pulse energy and high average output power and the acousto optic modulator can boost the intensity of the laser beam; the controller 80 is electrically connected to the first laser light source 11, the second laser light source 12 and the laser galvanometric scanning module 60, wherein the controller 80 timely adjusts the angle of the laser galvanometric scanning module 60 during processing, so as to achieve guiding the finished light beam 35 projected to any position of the two-dimensional coordinates of the work platform 50; the controller 80 controls the projection timing and energy of the first wavelength beam 111 and the second wavelength beam 121, and make the first finished light beam 351 and the second finished light beam 352 combine to form a composite light wave configuration 90, so as to make the processing of the composite material work piece 51 to be fast and precise.

Referring to FIG. 2B, the second embodiment 200 of the present invention, including: a first laser light source 11 for emitting a first wavelength beam 111 with wavelength of 532 nm; a second laser light source 12 for emitting a second wavelength beam 121 with wavelength of 1064 nm, arranged at the lateral side of the first laser light source 11; a first Bessel beam lens 20A and a second Bessel beam lens 20B individually arranged behind the first laser light source 11 and second laser light source 12, so as to form a first Bessel beam 201 and a second Bessel beam 202; a coaxial reflecting mirror 30 arranged on the optical path of the first Bessel beam 201, a second reflecting mirror 40B is arranged on the optical path of the second Bessel beam 202, the second reflecting mirror 40B deflects the second Bessel beam 202 to the coaxial reflecting mirror 30, and the coaxial reflecting mirror 30 is composed of two triangular prism mirrors 31, the combination surfaces 311 of the triangular prism mirrors 31 are individually coated with a coating 32 allowing the incoming first Bessel beam 201 and the second Bessel beam 202 to form a coaxial finished light beam 35, and the finished light beam 35 includes a first finished light beam 351 and a second finished light beam 352; a diffraction optical unit 70 is arranged behind the coaxial reflecting mirror 30 and on the optical path of the finished light beam 35, for adjusting the energy distribution of the finished light beam 35; a work platform 50 for supporting a work piece 51 for processing operations; a laser galvanometric scanning module 60 is arranged behind the diffraction optical unit 70 and above the work platform 50, the laser galvanometric scanning module 60 has a third reflecting mirror 61 and a X-Y scan lens 62, and by the reflection of the third reflecting mirror 61 and the focusing of the X-Y scan lens 62, the finished light beam 35 is guided to project on the required processing point of the work piece 51; a controller 80 includes a master oscillator power-amplifier or an acousto optic modulator, the master oscillator power-amplifier can achieve high pulse energy and high average output power and the acousto optic modulator can boost the intensity of the laser beam; the controller 80 is electrically connected to the first laser light source 11, the second laser light source 12 and the laser galvanometric scanning module 60, wherein the controller 80 timely adjusts the angle of the laser galvanometric scanning module 60 during processing, so as to achieve guiding the finished light beam 35 projected to any position of the two-dimensional coordinates of the work platform 50; the controller 80 controls the projection timing and energy of the first wavelength beam 111 and the second wavelength beam 121, and make the first finished light beam 351 and the second finished light beam 352 combine to form a composite light wave configuration 90, so as to make the processing of the composite material work piece 51 to be fast and precise.

Referring to FIG. 2C, the third embodiment 300 of the present invention, including: a first laser light source 11 for emitting a first wavelength beam 111 with wavelength of 532 nm; a second laser light source 12 for emitting a second wavelength beam 121 with wavelength of 1064 nm, arranged at the lateral side of the first laser light source 11; a coaxial reflecting mirror 30 and a second reflecting mirror 40B correspondingly arranged on the optical path of the first wavelength beam 111 and second wavelength beam 121, the second reflecting mirror 40B deflects the second wavelength beam 121 to the coaxial reflecting mirror 30, and the coaxial reflecting mirror 30 is composed of two triangular prism mirrors 31, the combination surfaces 311 of the triangular prism mirrors 31 are individually coated with a coating 32 allowing the incoming first wavelength beam 111 to penetrate and the second wavelength beam 121 to deflect to form a coaxial finished light beam 35, and the finished light beam 35 includes a first finished light beam 351 and a second finished light beam 352; a diffraction optical unit 70 is arranged behind the coaxial reflecting mirror 30 and on the optical path of the finished light beam 35, for adjusting the energy distribution of the finished light beam 35; a work platform 50 for supporting a work piece 51 for processing operations; a laser galvanometric scanning module 60 is arranged behind the diffraction optical unit 70 and above the work platform 50, the laser galvanometric scanning module 60 has a third reflecting mirror 61 and a X-Y scan lens 62, and by the reflection of the third reflecting mirror 61 and the focusing of the X-Y scan lens 62, the finished light beam 35 is guided to project on the required processing point of the work piece 51; a controller 80 includes a master oscillator power-amplifier or an acousto optic modulator; the controller 80 is electrically connected to the first laser light source 11, the second laser light source 12 and the laser galvanometric scanning module 60, wherein the controller 80 timely adjusts the angle of the laser galvanometric scanning module 60 during processing, so as to achieve guiding the finished light beam 35 projected to any position of the two-dimensional coordinates of the work platform 50; the controller 80 controls the projection timing and energy of the first wavelength beam 111 and the second wavelength beam 121, and make the finished light beam 35 having a composite light wave configuration 90 with at least one rectangular pulse 91 and at least one burst pulse 92, and then through the repeated conversion of the dual wavelengths in the composite light wave configuration 90 make the processing of the composite material work piece 51 to be fast and precise.

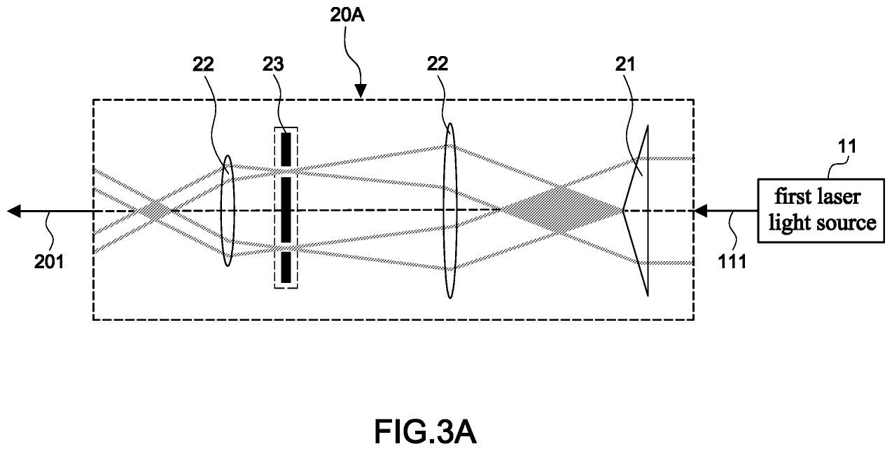

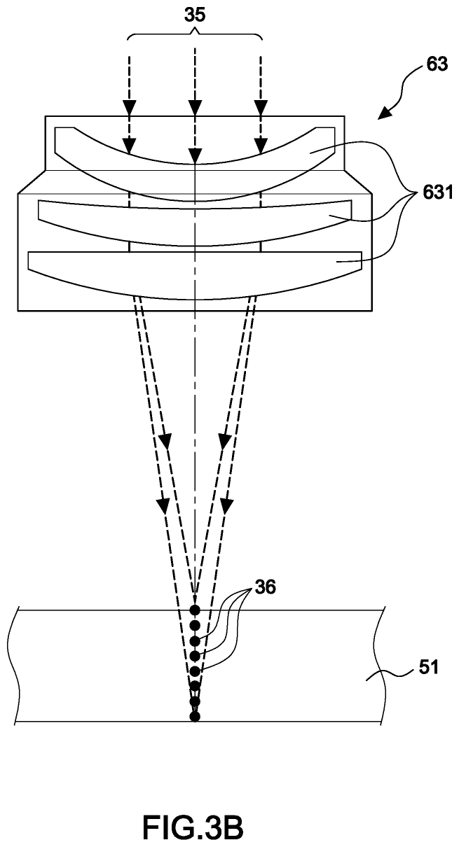

As shown in FIG. 3A, the first Bessel beam lens 20A has an axicon lens 21, multiple lenses 22, and a spatial filter 23 to make the first wavelength beam 111 forming a first Bessel beam 201 with long focal length; the structure of the first Bessel beam lens 20B and forming method second Bessel beam 202 is same as method shown in FIG. 3A. The aforementioned Bessel beam is a wave, which has the characteristics no dispersion in the direction of upward transmission, very small central light (only tens of microns), and self-recovery after encountering obstacles during the transmission process. On the other hand, the Bessel beam is a special non-diffraction beam, which has a large focus depth; it will form a stretching focus area when focusing, and has a unique longitudinal focus characteristic.

As shown in FIG. 3B, the multi focal length lens 63 is composed of multiple lenses 631; after the finished light beam 35 passes through this multiple lenses 631, multiple focal points 36 will be formed and arranged in a straight line from the surface of the work piece 51 to the inside, and the multiple focal points 36 can be formed on the work piece 51, at the same time, laser processing is applied at multiple focal points 36, so the present invention can let the finished light beam 35 accurately focus on the work piece 51.

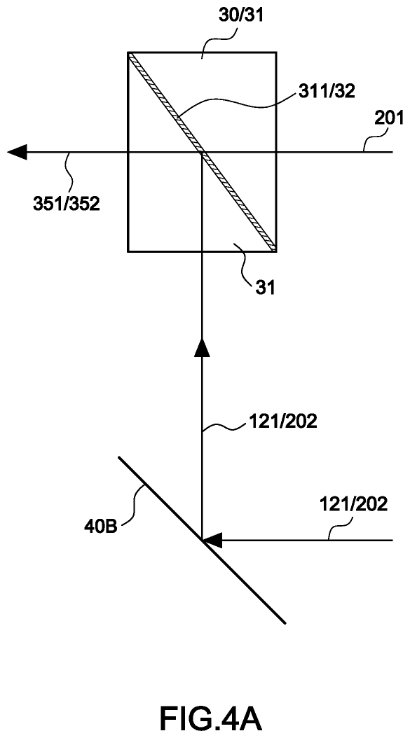

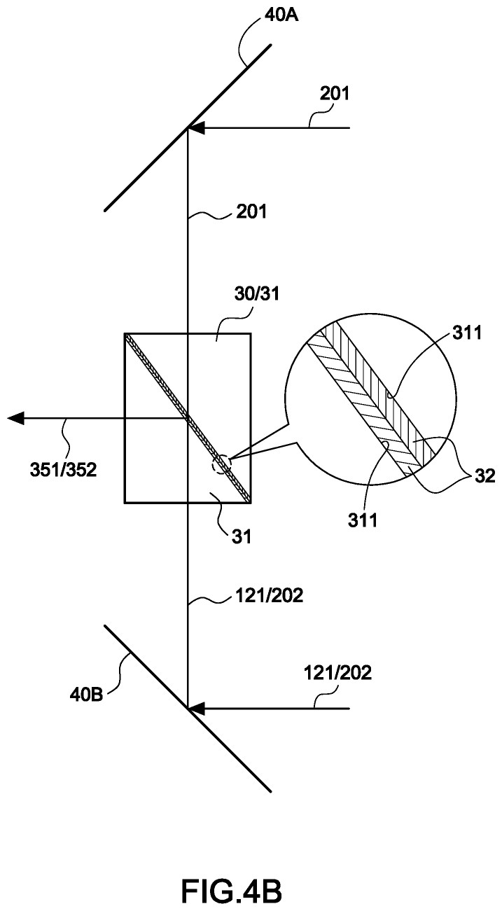

As above mentioned, the coaxial reflecting mirror 30 is coated with a coating 32 for the incoming light beam to penetrate or deflect, so as to form a coaxial finished light beam 35. As shown in FIG. 4A, in the first and second embodiment use the coaxial reflecting mirror 30 as the first structure to form coaxial finished light beam 35; wherein the coaxial reflecting mirror 30 is correspondingly arranged on the optical path of the first Bessel beam 201, a second reflecting mirror 40B is correspondingly arranged on the optical path of the second Bessel beam 202, the second reflecting mirror 40B deflects the second wavelength beam 121 or the second Bessel beam 202 to the coaxial reflecting mirror 30, and the coating 32 of the combination surfaces 311 of the triangular prism mirrors 31 of the coaxial reflecting mirror 30 allows the incoming first Bessel beam 201 to penetrate and the second wavelength beam 121 or the second Bessel beam to deflect, so as to form a coaxial first finished light beam 351 and a second finished light beam 352. Moreover, As shown in FIG. 4B, which is the second structure to form coaxial finished light beam 35 by the coaxial reflecting mirror 30; wherein including a first reflecting mirror 40A and a second reflecting mirror 40B correspondingly arranged on the optical path of the first Bessel beam 201 and the second wavelength beam 121 or the second Bessel beam 202, individually deflects the first Bessel beam 201, the second wavelength beam 121 or the second Bessel beam 202 to the coaxial reflecting mirror 30, and the coating 32 of the combination surfaces 311 of the triangular prism mirrors 31 of the coaxial reflecting mirror 30 allows the incoming the first Bessel beam 201 and the second wavelength beam 121 or the second Bessel beam 202 to deflect, so as to form coaxial first finished light beam 351 and a second finished light beam 352.

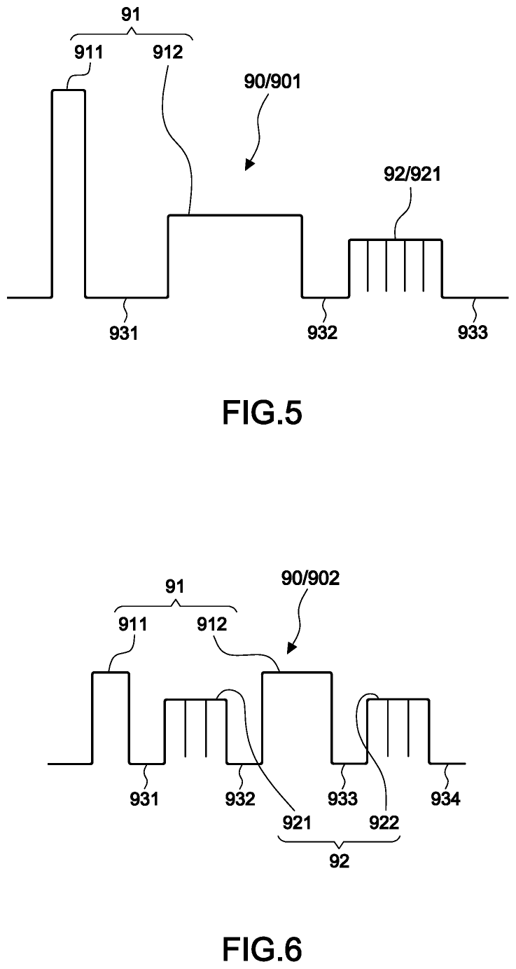

Referring to FIGS. 5-6, which showing the structure of the composite light wave configuration 90; the controller 80 is electrically connected to the first laser light source 11 and the second laser light source 12, the controller 80 controls the projection timing and energy of the first wavelength beam 111 and the second wavelength beam 121, and make the finished light beam 35 having a composite light wave configuration 90 with at least one rectangular pulse 91 and at least one burst pulse 92; wherein a first composite light wave configuration 901, as shown in FIG. 5, is a module having a periodic cycle, it comprises a rectangular pulse A 911, a rectangular pulse B 912, and a burst pulse A 921 in sequence, and each pulses has a retention time their own 931, 932, 933, the wavelength of the rectangular pulse A 911≤the rectangular pulse B 912, and the height and width of the burst pulse A 921 can be adjusted. Also, a second composite light wave configuration 902, as shown in FIG. 6, is a module having a periodic cycle, it comprises a rectangular pulse A 911, a burst pulse A 921, a rectangular pulse B 912, and a burst pulse B 922 in sequence, and each pulses has a retention time their own 931, 932, 933, 934, the wavelength of the rectangular pulse A 911 the rectangular pulse B 912, and the height and width of the burst pulse A 921 and the burst pulse B 922 can be adjusted.

The second embodiment 200 of the present invention arranges a first Bessel beam lens 20A and a second Bessel beam lens 20B individually arranged behind the first laser light source 11 and second laser light source 12, so as to form a first Bessel beam 201 and a second Bessel beam 202; through the coaxial reflecting mirror 30 with the coating 32, making the first Bessel beam 201 and the second Bessel beam 202 to form a coaxial finished light beam 35; through the controller 80 electrically connected to the first laser light source 11 and the second laser light source 12 to control the projection timing and energy of the first wavelength beam 111 and the second wavelength beam 121, and make the finished light beam 35 a form a composite light wave configuration 90 composed of a rectangular pulse 91 and a burst pulse 92; wherein the first composite light wave configuration 901 comprises two rectangular pulses 91 and a burst pulse 92, the second composite light wave configuration 902 comprises two rectangular pulses 91 and two burst pulses 92, and the wavelength of the rectangular pulse A 911≤the rectangular pulse B 912; through the repeated conversion of the dual wavelengths of the wavelength of the rectangular pulse A 911 and the rectangular pulse B 912 in the composite light wave configuration 90, using the rectangular pulse A 911 with a wavelength of 532 nm to cut the protective layer of the wafer, and then use the rectangular pulse B 912 with a wavelength of 1064 nm to cut the substrate of the lower layer of the wafer, so as to solve the disadvantage of two individual displacements required in the conventional wafer dicing; so the present invention make the processing of the composite material work piece 51 to be fast and precise. Moreover, characteristic. Moreover, the present invention can use the characteristics of the rectangular pulse 91 which releasing huge energy instantaneously in the composite light wave configuration 90, and the characteristics of the burst pulse 92 which avoiding energy failure through vibration, so the present invention can be applied to the processing of multi-layer structures of different materials, and it make the finished light beam 35 to achieve low energy consumption, narrow working hot spots, and high aspect ratio processing benefits. Moreover, the present invention uses the controller 80 to control the reflection of the third reflecting mirror 61 in the laser galvanometric scanning module 60 and the focusing of the X-Y scan lens 62, so as to achieve guiding the finished light beam 35 to any position of the two-dimensional coordinates of the work platform 50; since there is no need to displace the work platform 50 during laser processing of the work piece 51, therefore, the present invention can greatly improve the working efficiency.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A combined dual-wavelength laser light processing device, comprising:
a first laser light source for emitting a first wavelength beam;
a second laser light source for emitting a second wavelength beam, arranged at the lateral side of the first laser light source;
at least one Bessel beam lens is arranged behind one of the first laser light source or second laser light source, so that one of the first wavelength beam or second wavelength beam forms a Bessel beam;
a coaxial reflecting mirror composed of two triangular prism mirrors, the combination surfaces of the triangular prism mirrors are individually coated with a coating, the coaxial reflecting mirror is correspondingly arranged on the optical path of the Bessel beam and the wavelength beam of the first wavelength beam or second wavelength beam, so as to form a coaxial finished light beam, and the finished light beam includes a first finished light beam and a second finished light beam;
a diffraction optical unit is arranged behind the coaxial reflecting mirror and on the optical path of the finished light beam, for adjusting the energy distribution of the finished light beam;
a work platform for supporting a work piece for processing operations;
a laser galvanometric scanning module is arranged behind the diffraction optical unit and above the work platform, so as to achieve guiding the finished light beam to the work platform;
a controller electrically connected to the first laser light source, the second laser light source and the laser galvanometric scanning module, wherein the controller timely adjusts the angle of the laser galvanometric scanning module during processing, so as to achieve guiding the finished light beam projected to any position of the two-dimensional coordinates of the work platform; the controller controls the projection timing and energy of the first wavelength beam and the second wavelength beam, and make the first finished light beam and the second finished light beam combine to form a composite light wave configuration with at least one rectangular pulse and at least one burst pulse, and then through the repeated conversion of the dual wavelengths in the composite light wave configuration make the processing of the composite material to be fast and precise.

2. The combined dual-wavelength laser light processing device as claimed in claim 1, wherein the first wavelength beam has a wavelength of 532 nm, and the second wavelength beam has a wavelength of 1064 nm.

3. The combined dual-wavelength laser light processing device as claimed in claim 1, wherein the Bessel beam lens has an axicon lens, multiple lenses, and a spatial filter to form a Bessel beam with long focal length.

4. The combined dual-wavelength laser light processing device as claimed in claim 1, wherein the Bessel beam lens is a first Bessel beam lens, the Bessel beam is a first Bessel beam.

5. The Combined dual-wavelength laser light processing device as claimed in claim 4, wherein further includes a second Bessel beam lens, which corresponds to the first Bessel beam lens, and is arranged behind one of the other first laser light source or second the laser light source, so as to make one of the other first wavelength beam or second wavelength beam to form a second Bessel beam; and the coaxial reflecting mirror is correspondingly arranged on the optical path of the first Bessel beam and the second Bessel beam to form a coaxial finished light beam.

6. The combined dual-wavelength laser light processing device as claimed in claim 5, wherein the coaxial reflecting mirror is correspondingly arranged on the optical path of the first Bessel beam, a second reflecting mirror is correspondingly arranged on the optical path of the second Bessel beam, the second reflecting mirror deflects the second Bessel beam to the coaxial reflecting mirror, and the coating of the coaxial reflecting mirror allows the incoming first Bessel beam to penetrate and the second Bessel beam to deflect, so as to form a coaxial finished light beam.

7. The combined dual-wavelength laser light processing device as claimed in claim 5, wherein further includes a first reflecting mirror and a second reflecting mirror correspondingly arranged on the optical path of the first Bessel beam and the second Bessel beam, deflect the first Bessel beam and the second Bessel beam to the coaxial reflecting mirror, and the coating of the coaxial reflecting mirror allows the incoming first Bessel beam and the second Bessel beam to deflect, so as to form a coaxial finished light beam.

8. The combined dual-wavelength laser light processing device as claimed in claim 1, wherein the laser galvanometric scanning module has a third reflecting mirror and a X-Y scan lens, and by the reflection of the third reflecting mirror and the focusing of the X-Y scan lens, the finished light beam is guided to project on the required processing point of the work piece.

9. The combined dual-wavelength laser light processing device as claimed in claim 1, wherein the controller includes a master oscillator power-amplifier or an acousto optic modulator for controlling the projection timing and energy of the first wavelength beam and the second wavelength beam, and make the first finished light beam and the second finished light beam combine to form a composite light wave configuration.

10. The combined dual-wavelength laser light processing device as claimed in claim 1, wherein the composite light wave configuration has a first composite light wave configuration with a periodic cycle, which includes a rectangular pulse A, a rectangular pulse B, and a burst pulse A in sequence, each pulses has a retention time their own, and the wavelength of the rectangular pulse A the rectangular pulse B, also the height and width of the burst pulse A can be adjusted.

11. The combined dual-wavelength laser light processing device as claimed in claim 1, wherein the composite light wave configuration has a second composite light wave configuration with a periodic cycle, which includes a rectangular pulse A, a burst pulse A, a rectangular pulse B, and a burst pulse B in sequence, each pulses have a retention time their own, and the wavelength of the rectangular pulse A≤the rectangular pulse B, also the height and width of the burst pulse A and the burst pulse B can be adjusted.

12. A combined dual-wavelength laser light processing device, comprising:
a first laser light source for emitting a first wavelength beam;
a second laser light source for emitting a second wavelength beam, arranged at the lateral side of the first laser light source;
a coaxial reflecting mirror and a second reflecting mirror are arranged on the optical path of the first wavelength beam and the second wavelength beam correspondingly, the second reflecting mirror deflects the second wavelength beam to the coaxial reflecting mirror, and the coaxial reflecting mirror are composed of two triangular prism mirrors, the combination surfaces of the triangular prism mirrors are individually coated with a coating, which allow the incoming first wavelength beam to penetrate and the second wavelength beam to deflect, so as to form a coaxial finished light beam, and the finished light beam includes a first finished light beam and a second finished light beam;
a diffraction optical unit is arranged behind the coaxial reflecting mirror and on the optical path of the finished light beam, for adjusting the energy distribution of the finished light beam;
a work platform for supporting a work piece for processing operations;
a laser galvanometric scanning module is arranged behind the diffraction optical unit and above the work platform, so as to achieve guiding the finished light beam to the work platform;
a multi focal length lens arranged between the laser galvanometric scanning module and the work platform for precisely focusing the finished light beam on the work piece;
a controller electrically connected to the first laser light source, the second laser light source and the laser galvanometric scanning module, wherein the controller timely adjusts the angle of the laser galvanometric scanning module during processing, so as to achieve guiding the finished light beam projected to any position of the two-dimensional coordinates of the work platform; the controller controls the projection timing and energy of the first wavelength beam and the second wavelength beam, and make the first finished light beam and the second finished light beam combine to form a composite light wave configuration with at least one rectangular pulse and at least one burst pulse, and then through the repeated conversion of the dual wavelengths in the composite light wave configuration make the processing of the composite material to be fast and precise.

13. The combined dual-wavelength laser light processing device as claimed in claim 12, wherein the first wavelength beam has a wavelength of 532 nm, and the second wavelength beam has a wavelength of 1064 nm.

14. The combined dual-wavelength laser light processing device as claimed in claim 12, wherein the laser galvanometric scanning module has a third reflecting mirror and a X-Y scan lens, and by the reflection of the third reflecting mirror and the focusing of the X-Y scan lens, the finished light beam is guided to project on the required processing point of the work piece.

15. The combined dual-wavelength laser light processing device as claimed in claim 12, wherein the controller includes a master oscillator power-amplifier or an acousto optic modulator for controlling the projection timing and energy of the first wavelength beam and the second wavelength beam, and make the first finished light beam and the second finished light beam combine to form a composite light wave configuration.

16. The combined dual-wavelength laser light processing device as claimed in claim 12, wherein the composite light wave configuration has a first composite light wave configuration with a periodic cycle, which includes a rectangular pulse A, a rectangular pulse B, and a burst pulse A in sequence, each pulses has a retention time their own, and the wavelength of the rectangular pulse A the rectangular pulse B, also the height and width of the burst pulse A can be adjusted.

17. The combined dual-wavelength laser light processing device as claimed in claim 12, wherein the composite light wave configuration has a second composite light wave configuration with a periodic cycle, which includes a rectangular pulse A, a burst pulse A, a rectangular pulse B, and a burst pulse B in sequence, each pulses have a retention time their own, and the wavelength of the rectangular pulse A≤the rectangular pulse B, also the height and width of the burst pulse A and the burst pulse B can be adjusted.
